(19) United States
(12) Patent Application Publication
(10) Pub. No.: US 2010/0175749 A1
(43) Pub. Date: Jul. 15, 2010

(54) SOLAR CELL AND METHOD FOR MANUFACTURING METAL ELECTRODE LAYER TO BE USED IN THE SOLAR CELL

(76) Inventors: Eishi Tsutsumi, Kanagawa-ken (JP); Tsutomu Nakanishi, Tokyo (JP); Ryota Kitagawa, Tokyo (JP); Akira Fujimoto, Kanagawa-Ken (JP); Koji Asakawa, Kanagawa-Ken (JP); Satoshi Mikoshiba, Kanagawa-Ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/441,036

(22) PCT Filed: Jan. 29, 2009
(86) PCT No.: PCT/JP2009/051917

§ 371 Date: Mar. 12, 2009

(30) Foreign Application Priority Data
Mar. 24, 2008 (JP) 2008 0725224

(51) Int. Cl. H01L 31/0224; H01L 31/18

(52) U.S. Cl. 136/256; 438/98; 257/E31.124

(57) ABSTRACT

A solar cell includes: a first electrode layer formed on a substrate; a generating layer formed on the first electrode layer; and a second electrode layer formed on the generating layer, at least one of the first electrode layer and the second electrode layer being a metal electrode layer having optical transparency, the metal electrode layer having a plurality of openings that penetrate through the metal electrode layer. The metal electrode layer includes metal parts, any two metal parts of the metal electrode layer continues to each other without a cut portion, the metal electrode layer has a film thickness in the range of 10 nm to 200 nm, and sizes of the openings are equal to or smaller than ½ of the wavelength of light to be used for generating electricity.

### BACKGROUND OF THE INVENTION

1. Field of the Invention

The present invention relates to a solar cell, and more particularly, to a metal electrode layer to be used in the solar cell. The present invention also relates to a method for manufacturing the metal electrode layer to be used in the solar cell.

2. Related Art

The energy of sunlight falling to the entire earth is said to be 100,000 times larger than the electric power consumption of the entire world, and we are surrounded by an enormous amount of energy resources, even when not doing on industrial activities. To make good use of the enormous energy resources, studies have been made on the techniques related to solar cells utilizing the energy of sunlight. A solar cell is a device for converting the energy resource (the sunlight) into electric energy human beings can easily use. Solar cells are considered to be essential devices in solving today's energy shortage problem.

The solar cells available today can be classified into silicon (Si) solar cells and compound-semiconductor solar cells. The silicon solar cells can be further classified into a single-crystal Si type, a poly-Si type, an amorphous Si type, a microcrystalline Si type, and tandem structures of those types of cells. Those classified types of silicon solar cells vary in conversion efficiency, costs, and processability, and therefore, are selected in accordance with the purposes and places of use.

Each of the types of solar cells is now briefly described. Among the Si solar cells, single-crystal Si solar cells have the highest conversion efficiency, and the conversion efficiency of some of the single-crystal Si solar cells available on the market is as high as 20% in practice. The production costs of poly-Si solar cells are lower than those of single-crystal Si solar cells, and poly-Si solar cells have the largest market share in recent years, because of their good balance between stable performances and costs. Further, amorphous Si solar cells have lower efficiency than crystalline Si solar cells, but the absorption coefficient of an amorphous Si film is several hundreds times larger than that of a crystalline Si film. Accordingly, it is possible to form a thinner light absorption layer with an amorphous Si film. Because of the above facts, amorphous Si solar cells are inexpensive, do not require many materials, and can be easily manufactured. Accordingly, amorphous Si solar cells are suitable in electronic calculators and the likes. Meanwhile, the microcrystalline silicon type involves a microcrystalline thin film formed by CVD or the like. The microcrystalline silicon type may be regarded as one of polycrystalline types, but also exhibits amorphous properties, depending on the conditions for film formation. The microcrystalline silicon type is abbreviated as μc-Si or the like. Microcrystalline Si solar cells can be manufactured by a relatively new technique that does not involve cutting an ingot and reduces the use of resources. Also, by some manufacturing method, films for microcrystalline Si solar cells can be manufactured at a temperature as low as 200° C., and any kind of substrate can be used in microcrystalline Si solar cells.

Tandem solar cells are manufactured by stacking solar cells with different light absorption wavelengths, so that wider wavelength ranges can be electrically converted. An example stacked structure for a tandem solar cell is formed by stacking the above amorphous silicon layer and the above microcrystalline silicon layer.

While there are various types of solar cell as described above, there is a demand for lower production costs in the entire field of the solar cell technology, so as to facilitate popularization of solar cells. Particularly, the costs of transparent electrodes account for a large percentage of the production costs. Therefore, development of high-quality and inexpensive transparent conductive films is expected so as to reduce the costs of transparent electrodes. The transparent electrodes for solar cells are required to have not only high transmission properties but also excellent electric properties. This is because, if the electric properties at the electrode portions are poor when the light energy generated in a solar cell is taken out as a current, energy loss is caused at the portions.

To manufacture an electrode for a solar cell of the single-crystal Si type or the poly-Si type, a metal electrode is formed on the sunlight incident face side by a technique such as screen printing. When an electrode for a solar cell is manufactured, a regular procedure is carried out by applying a paste containing conductive metal such as silver particles, glass frit, a resin binder, a thinner and an additive if necessary, and then performing a firing process.

In a case where the surface resistance of the semiconductor of the generating layer is high as in a compound-semiconductor solar cell or an amorphous Si solar cell, the carrier diffusion distance is short, and is not sufficient for carrying carriers. Therefore, indium tin oxide (hereinafter referred to as ITO) that allows contacts between the electrodes and the generating layer over the entire surface, or a zinc-oxide transparent conductive film is used.

When an electrode for a solar cell of the single-crystal Si type or the poly-Si type is manufactured, the electrode is normally formed on the sunlight incident face side by a technique such as screen printing, as described above.

However, if light is blocked by a fired surface electrode in a solar cell, the amount of light incident on the solar cell becomes smaller. To counter this problem, a comb-like electrode structure called a finger-electrode structure is most often used. In such a structure, carriers excited by light are generated not immediately below the electrode, but on both sides. The carriers travel in a horizontal direction to reach the electrode, and flow into an external circuit through the thin fingers. The pitch of the electrode fingers is determined by the carrier diffusion distance in the generating layer and the surface resistance of the generating layer cell. For example, in a regular single-crystal Si solar cell, fingers of 75 μm in width may be arranged at 2 mm intervals, or fingers of 127 μM width are arranged at 4 mm intervals.

According to the technique involving those electrode fingers, a decrease ranging from 5% to 7% is caused in the effective light incident area, and the generating efficiency becomes lower accordingly. Also, the carriers generated in the generating layer are trapped and recoupled before reaching the electrode, and loss is caused due to the traps and recoupling. Therefore, it is considered that a further decrease in efficiency is actually caused though not appearing in figures. This leaves problems to be solved in the electrode structure.

In a compound-semiconductor solar cell or an amorphous Si solar cell, ITO or a zinc-oxide transparent conductive film is used, so as to achieve contacts on the entire surface. Because of this, the carrier recoupling is reduced, but the resistivity of such a transparent conductive film is a hundred or more times higher than the resistivity of a metal. Because of this, the resistance loss becomes larger, as the film thickness is made smaller to achieve sufficient light transmission. Heat loss and the likes also lead to a decrease of the generating efficiency. Furthermore, such a transparent conductive film is formed through a sputtering process that is normally a vacuum process. As a result, the costs required in the manufacture become higher.

### SUMMARY OF THE INVENTION

The present invention has been made in view of these circumstances, and an object thereof is to provide a solar cell that includes an optically-transparent metal electrode layer that has low resistivity and high transmission properties, and is made of an inexpensive material.

According to a first aspect of the present invention, there is provided a solar cell including: a first electrode layer formed on a substrate; a generating layer formed on the first electrode layer; and a second electrode layer formed on the generating layer, at least one of the first electrode layer and the second electrode layer being a metal electrode layer having optical transparency, the metal electrode layer having a plurality of openings that penetrate through the metal electrode layer, the metal electrode layer including metal parts, any two metal parts of the metal electrode layer continuing to each other without a cut portion, the metal electrode layer having a film thickness in the range of 10 nm to 200 nm, and sizes of the openings being equal to or smaller than ½ of the wavelength of light to be used for generating electricity.

According to a second aspect of the present invention, there is provided a method for manufacturing the metal electrode layer of the solar cell according to any one of the first and second aspects, the method comprising: generating dot-like microdomains that are phase separation forms of a block copolymer film; and forming the metal electrode layer having openings by performing etching, with patterns of the microdomains being used as a mask.

According to a third aspect of the present invention, there is provided a method for manufacturing the metal electrode layer of the solar cell according to any one of the first and second aspects, the method comprising: preparing a transparent substrate; forming an organic polymer layer on the transparent substrate; forming an inorganic layer on the organic polymer layer; generating dot-like microdomains of a block copolymer film on the inorganic layer; forming pillar-like portions with an organic polymer and an inorganic material on a surface of the transparent substrate by transferring patterns of the microdomains of the block copolymer film onto the organic polymer layer and the inorganic layer; forming a metal layer at spaces between the formed pillar-like portions; and forming the metal electrode layer by removing the organic polymer.

### BRIEF DESCRIPTION OF THE DRAWINGS

FIGS. 1A and 1B are diagrams showing an example of the patterns on a metal electrode layer having openings according to an embodiment;

FIG. 2 is an electron microscope photograph showing an example of the patterns on the metal electrode layer having openings according to an embodiment;

FIGS. 3A to 3E are diagrams showing an example of the process for manufacturing the metal electrode layer having openings according to an embodiment;

FIG. 4 is a cross-sectional view of a single-crystal Si solar cell that includes the metal electrode layer having openings according to an embodiment;

FIG. 5 is a cross-sectional view of a polycrystalline Si solar cell that includes the metal electrode layer having openings according to an embodiment;

FIG. 6 is a cross-sectional view of an amorphous Si solar cell that includes the metal electrode layer having openings according to an embodiment; and

FIG. 7 is a cross-sectional view of a compound-semiconductor solar cell that includes the metal electrode layer having openings according to an embodiment.

### DETAILED DESCRIPTION OF THE INVENTION

In the present invention, the electrode to be placed in the light incident face of a solar cell is a nanomesh structure that has numerous minute holes formed in a metal thin film.

The advantages of the present invention include the following two aspects. One is that a rare metal such as the indium in ITO that is used as a conventional transparent electrode is not used. The other one is that electric conduction is caused by the free electrons in the metal, and therefore, it is possible to achieve higher electric conductivity than the electric conductivity of an oxide semiconductor material formed with a semiconductor doped with carriers.

First, the transmission of light through a metal thin film having holes smaller than the light wavelength is described.

The phenomenon caused when light is emitted onto minute openings that are formed in a metal film and are smaller than the wavelength has been explained on the basis of the Bethe's Theory of Diffraction (see “Theory of Diffraction by Small Holes”, H. A. Bethe, Physical Reviews 66, 163-82, 1944). If the metal thin film is a perfect conductor and has an infinite thinness, the intensity A of completely-polarized light passing through openings having a radius a that is smaller than the wavelength λ. is expressed as follows:

A=[64k⁴a⁶(1−⅜ sin 2θ)]/27π (1)

where k represents the wavenumber of the light (k=2π/λ), and θ represents the incidence angle.

Further, if the light intensity is divided by the area πa² of the openings in the case of normal incidence, the efficiency η of the transmitted light in the light emitted onto the openings is obtained, and is expressed as:

η=64(ka)⁴/27π² (2)

Since the wavenumber k is proportional to the inverse of the wavelength λ, this equation means that the light transmission efficiency η is proportional to the fourth power of (a/λ). Accordingly, it has been considered that the light transmission rapidly decreases as the opening radius a becomes smaller.

This theory is applied to a mesh shield in a microwave region or the like, or is used as the theory of the Faraday gauge, and often matches actual phenomena. Accordingly, if an electronic oven that uses electromagnetic waves of 12 cm in wavelength at 2.45 GHz is surrounded by a mesh metal film having openings of 1 mm in radius, leakage of electromagnetic waves hardly occurs.

With the thickness of the metal thin film being taken into consideration, the openings formed in the thin film are regarded as the hollow waveguides formed in the metal for incident light. Normally, there is a specific range set to the light frequencies that can be conducted through waveguides. The frequency range depends on the diameter of each wavelength. With a given opening size R, light of a certain frequency or lower cannot propagate in the waveguide, and attenuates. The light frequency serving as the threshold value here is called the cutoff frequency. The wavelength corresponding to the cutoff frequency depends on the opening size, and the wavelength of incident light is approximately ½ of the opening size. Therefore, if the light wavelength is equal to or smaller than ½ of the opening size R, light can propagate in the openings. If the light wavelength is greater than ½ of the opening size R, light cannot propagate in the openings, and attenuates in an exponential fashion.

As described above, if the opening size is smaller than the light wavelength, especially if the opening size is equal to or smaller than ½ of the light wavelength, it is normally considered that transmission of light through the openings is difficult.

However, the inventors made an intensive study on light and minute processing of metal thin films, to discover that a light transmission rate equal to or higher than the transmission rate calculated according to the above mentioned theory can be achieved by forming numerous holes smaller than the light wavelength in a metal thin film. This phenomenon can be explained as follows.

When light of lower frequency than plasma frequency is emitted onto a metal, the free electrons in the metal are polarized due to an electric field of the light. This polarization is induced in such a direction as to cancel the optical electric field. As the induced electric polarization shuts off the optical electric field, the light cannot be transmitted through the metal, and so-called plasma reflection occurs. If the structure size of the material in which the electron polarization is induced is made sufficiently smaller than the light wavelength, the movement of the electrons is restricted by the geometric structure of the metal, and the electrons cannot shut off the electric field of the light. As a result, transmission of a greater amount of light than the amount expected from the total sum of the areas of the minute openings can be expected.

The following is a detailed description of the metal electrode layer having optical transparency to be used in a photoelectric conversion device in accordance with an embodiment of the present invention, and a method for manufacturing the metal electrode layer having optical transparency, with reference to the accompanying drawings.

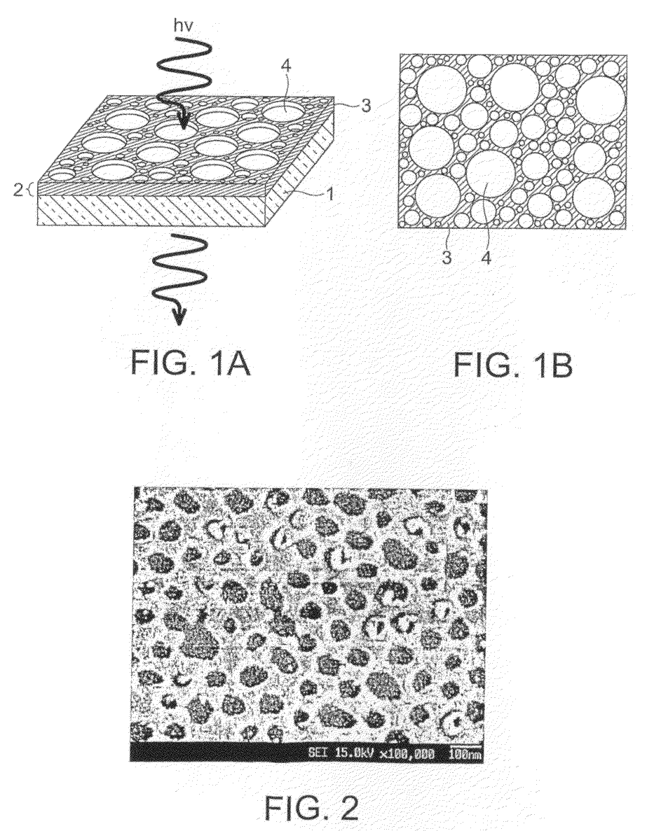

An example of the metal electrode layer having optical transparency for solar cells in accordance with a first embodiment of the present invention is shown in FIGS. 1A and 1B. FIG. 1A is a perspective view of the metal electrode layer having optical transparency. FIG. 1B is a plan view of the metal electrode layer having optical transparency. This transparent electrode has a metal electrode layer 2 formed on a flat and smooth transparent substrate 1. The metal electrode layer 2 has metal parts 3 and minute openings 4 penetrating through the metal parts 3. The metal electrode layer 2 functions as an electrode, and at the same time, can transmit light having a wavelength in the visible range.

In other words, the metal electrode layer having optical transparency in accordance with the present invention has higher transparency than expected from the total sum of the areas of the openings 4 formed in the metal parts 3, or characteristically transmits light by reducing in principle the reflection properties inherent to the metal parts 3.

As the openings 4 sufficiently smaller than the wavelength of light incident on the electrode are provided, the metal electrode layer 2 functions as an electrode layer having optical transparency though being a metal in accordance with the following principles. The linear distance between the continuous metal parts 3, with no openings 4 being interposed in between, is equal to or smaller than ⅓ of the wavelength of the light. Accordingly, the movement of free electrons induced by the electric field of the light when the light is emitted onto the electrode is hindered, and the metal electrode layer 2 becomes transparent to the light.

First, the principles of a response to light emission onto a material are described. If the mean scattering time of free electrons is set sufficiently shorter than an oscillation cycle of light according to the Drude theory that describes polarization of free electrons in terms of the classical dynamics, the dielectric function ε(ω) is expressed as follows:

ε(ω)=ε_{b}(ω)−ω_{P}²/ω² (3)

where ω_{P}²=ne²/m×εₒ is the plasma frequency of conduction electrons, n represents the carrier density, e represents the charge, n represents the effective mass, and εₒ represents the dielectric constant of vacuum. The first term of the equation (3) is the contribution of the dipole of the metal, and is close to 1 in this case. The second term is the contribution from the conduction electrons.

In other words, the plasma frequency is the function of the carrier density n. When ωₒ is greater than ω, the dielectric function ε(ω) exhibits a negative value, and the light emitted onto the material is plasma-reflected. If ω is greater than ωₒ, the dielectric function ε(ω) exhibits a positive value, and the light is transmitted. Accordingly, the plasma frequency can be regarded as the threshold value between reflection and transmission when there is a response to light from the material.

Since a typical metal has the plasma frequency existing in the ultraviolet region, visible light is reflected. In the case of Ag, for example, the carrier density n is approximately 6.9×10²² cm⁻³, and the wavelength corresponding to the plasma frequency is in a ultraviolet area of approximately 130 nm.

As for the ITO of an oxide semiconductor used in an amorphous solar cell or the like, the wavelength corresponding to the plasma frequency is in the infrared region. Since the carrier density is proportional to the electric conductivity and is inversely proportional to the electric resistivity, the addition of dopant for lowering the electric resistivity leads to an increase of the plasma frequency. Therefore, if the addition of dopant is increased, plasma reflection occurs on the long-wavelength side of visible light when the addition of dopant reaches a certain value. As a result, the transmission rate becomes lower.

As described above, the wavelength corresponding to the plasma frequency should be in the infrared range, so as to secure a sufficient transmission rate in the visible region to be used by a solar cell to generate electricity with the above described oxide semiconductor material. Therefore, the upper limit is set to the carrier density according to the above principles. For those reasons, the carrier density n in a normally manufactured ITO is approximately 0.1×10²² cm⁻³, which is a twentieth part to ninetieth part of the carrier density of a metal. The lower limit of the resistivity calculated from this value is approximately 100 μΩ·cm, and it is difficult to make the resistivity lower than that in principle.

To counter the above problems, a metal mesh electrode that is 15 μl or less in thickness and 25 μm or less in line width, and has openings of 50 μm to 2.5 mm is formed on a transparent substrate. The openings are filled with transparent resin film, and an ITO film is formed over the entire surface (see JP-A 2005-332705 (KOKAI), for example). By this method, however, the metal mesh electrode plays only an auxiliary role in the electric conduction of the ITO film, and does not solve the above problems.

As described so far, the electrode on the sunlight incident side of the solar cell is also required to have a high light transmission rate and low resistivity. However, there is a trade-off relationship between a high light transmission rate and low resistivity, as mentioned above. Therefore, it is difficult to further increase the efficiency only with a conventional finger electrode structure or a transparent conductive film of an oxide semiconductor.

The present invention has been made in view of those circumstances.

Here, the “wavelength of the light to be used to generate electricity” is the wavelength of the light that is incident onto the metal electrode layer having optical transparency. Accordingly, the wavelength can vary in a wide range. For example, with a crystalline Si material, it is possible to use light of approximately 1.2 μm or less in the near-infrared region. With an amorphous Si material, it is possible to use light of approximately 750 nm or less of sunlight. Meanwhile, the “linear distance between metal parts” is the longest linear distance between any two points on the electrode surface, with no openings being interposed between the two points.

The inventors made an intensive study on those structures, to discover that completely-polarized light can be transmitted through the entire electrode if minute openings are formed in the metal electrode film, and the linear distance between the continuous metal parts not interposing any of the minute openings is ⅓ or less of the wavelength of the light incident on the electrode, or more preferably, ⅕ or less of the wavelength of the light incident on the electrode. Meanwhile, any two points in the metal electrode continue to each other without a cut, or the metal parts are continuous on the entire surface, the metal electrode film maintains the function as an electrode. Also, as the resistivity becomes lower with the proportional volume of the minute openings, the high electric conductivity of the metal is maintained.

If the portion at which the linear distance between the continuous metal parts is ⅓ or less of the light wavelength constitutes 80% or more of the entire surface area in the electrode, or more preferably, 95% or more of the entire surface area in the electrode, the optical transparency is not degraded. Therefore, it is preferable to form a structure including such a portion at the above ratio.

The minute openings have random relative positions in the electrode face. In other words, the relative positions of the minute openings are isotropic. The reason for the relative positions according to the principles of light transmission is that, if the minute openings form a hexagonally-symmetrical, triangular-lattice periodic structure, the metal parts become continuous in three axial directions, and polarized light that cannot isotropically hinder the movement of free electrons is generated.

To determine whether the relative positions of the minute openings are isotropic, the following techniques may be used. An electron microscope photograph or an atomic force microscope photograph of the upper face of the metal electrode layer having the minute openings is first obtained. The photograph is then subjected to a two-dimensional Fourier transform to form a so-called reciprocal lattice space image. If the minute openings are located at periodic relative positions, a clear spot appears in the reciprocal lattice space image. If the minute openings are located at random, isotropic relative positions, the reciprocal lattice space image has a ring-like shape that can be used in the determination.

Next, the thickness of the metal electrode layer having optical transparency is described. The metal electrode layer may be formed by a regular film forming technique, such as a resistance heating vapor deposition technique, an electron beam (EB) vapor deposition technique, or a sputtering technique. If the film thickness of the metal electrode layer is very small, the metal is formed with continuous aggregates of very small crystals. If the film thickness is approximately 10 nm or less, it is often difficult to achieve stable electric conduction. If the film thickness is made large, a low-resistance film can be achieved. If the film thickness is approximately 200 nm or more, it is difficult to achieve optical transparency sufficient for the film to function as the metal electrode layer having optical transparency.

The shapes of the openings are not particularly limited, as long as the above requirements are satisfied. For example, the openings may each have a cylindrical shape, a conic shape, a three-sided pyramidal shape, a four-sided pyramidal shape, or some other cylindrical or pyramidal shape. Alternatively, the openings may have two or more of those shapes together. Even if openings of various shapes and sizes exist in the transparent electrode of the present invention, the effects of the present invention are not lost. Rather, it is preferable that the openings have various sizes, because the linear distance between continuous metal parts tends to be long in that case. In such a case where the openings have various sizes, the mean value of the sizes of the openings is shown as the opening size.

When light is emitted onto a material, a phenomenon such as scattering or diffraction is caused. Scattering of light through the openings depends on the opening size. As the opening size becomes smaller with respect to the wavelength of the incident light, the influence of the scattering becomes smaller. When a periodic structure is formed at an interface between the incident side and the exit side having different refractive indexes, and certain requirements are satisfied, light diffraction is caused. If the opening size is equal to or smaller than half the light wavelength, the influence of the diffraction can also be reduced, though depending on the refractive index difference at the interface.

The openings of the present invention may be filled with air or a substance such as a dielectric material, and the effects of the present invention are still maintained. Further, a transparent material such as glass or melt glass may cover or may be stacked as a protection film on the electrode on the sunlight incident face side.

In the case of a crystalline Si solar cell or the like, the substrate is a base member that is provided on the back-face electrode side of the solar cell element. In the case of an amorphous Si solar cell in which the light incident face is on the opposite side from the side in the case of a crystalline Si solar cell, which is on the side of the substrate such as a glass substrate, the substrate is a base member that faces the light receiving face.

The substrate of the generating layer of the present invention can be arbitrarily selected according to the usage. For example, if the substrate needs to be transparent, examples of the substrate include an amorphous quartz (SiO₂) substrate, a Pyrex (a registered trade name) glass substrate, a molten silica substrate, an artificial fluorite substrate, a soda glass substrate, a potassium carbonate glass substrate, a tungsten glass substrate. Other than that, it is also possible to select a regular plastic substrate or a ceramics substrate, according to the required physical properties. If the substrate is required to have flexibility, a polyethylene terephthalate (PET) substrate, a polyimide substrate, or the like can be selected.

As the generating layer, a compound semiconductor layer such as a GaAs layer, an InP layer, a CdTe layer, a CuInGaSe (CIGS) layer may be used, other than the above silicon layers. The metal electrode layer having optical transparency of the present invention can also be used in solar cells including those layers.

The following considerations were obtained as a result of measurement carried out on samples of optical-transparent metal electrode layers having minute openings and samples of solar cells including the metal electrode layers.

FIG. 2 is an electron microscope photograph of the metal electrode layer having openings of this embodiment, taken from above. The metal electrode layer having those openings was formed by depositing aluminum with the use of a block copolymer thin film as a template. By this technique, it is possible to form large-area opening patterns of 100 nm or smaller that could not be formed by light or electron lithography. Even if the same structure as above can be produced by improved optical lithography or improved electron lithography in the future, the structure still has the same functions as the metal electrode layer having optical transparency of the present invention.

In the present invention, the shape of a block polymer is used as a template. Accordingly, an expensive device or the like is not necessary, and a desired structure can be readily formed in an optimum fashion. Through a self-organizing phenomenon of such a block polymer, an etching mask is formed, and concavities and convexities are formed on the base member with the use of the etching mask. In this manner, a metal electrode layer having openings of desired shapes can be obtained.

The materials to be used in embodiments of the present invention are now described in detail.

The metal to form electrodes in the present invention can be arbitrarily selected. Here, the metal is formed with a metal element that is a conductor as it is, has metallic luster, has ductibility, and is in a solid state at room temperature. Alternatively, the metal may be an alloy of such metals. It is preferable that the material to be selected here absorbs little light in the wavelength range of the light to be used, and has high electric conductivity. Specific examples of such materials include Al, Ag, Au, Pt, Ni, Co, Cr, Cu, and Ti, and more preferable examples among them are Al, Ag, Pt, Ni, and Co.

In this embodiment, a diblock copolymer that is a combination of an aromatic-ring polymer and an acrylic polymer is used. However, if one of the components in the diblock copolymer can be selectively removed as described later, the combination is not limited to the above. Also, the same structure may be produced with the use of an electron beam (EB) drawing device or by the nanoimprint technique, by which a structure with concavities and convexities is transferred with the use of a polymer having minute concavities and convexities as a stamp.

The reason that the diblock copolymer formed with a combination of an aromatic-ring polymer and an acrylic polymer is used in this embodiment is that there is a large difference in dry etching tolerability between the two kinds of polymers. Examples of the aromatic-ring polymer include polystyrene, polyvinylnaphthalene, polyhydroxystyrene, and derivatives of those materials. Examples of the acrylic polymer include alkylmethacrylates such as polymethylmethacrylate polybutylmethacrylate, and polyhexylmethacrylate, polyphenylmethacrylate and polycyclohexylmethacrylate, and derivatives of those materials. Instead of those methacrylates, acrylates can be used to achieve the same characteristics. Among those materials, a diblock copolymer of polystyrene and polymethylmethacrylate excels in dry etching tolerability and the likes.

To be used as a template according to a manufacturing method of the present invention, a block polymer should have a nanoscale dotted domain that is sufficiently formed through self-organization. Therefore, a composition having a dotted structure is most suitable for the purpose of the present invention among a number of separation forms of the phase separations of block copolymers.

The inventors discovered a method for obtaining the phase separation form of a block copolymer having a dotted structure having 50 nm to 70 nm cycles. The phase-separated dot-like patterns are transferred onto the substrate or the generating layer by the later described method. A metal electrode is deposited onto the structure having the patterns transferred thereon, and the pattern-transferred portion is removed. Thus, the structure can be used as the metal electrode layer having optical transparency.

To produce a metal transparent electrode layer having patterns with higher resolution than the highest possible resolution of regular lithography as required in the present invention, it is preferable to use a technique involving a block copolymer as an etching mask or a liftoff mask.

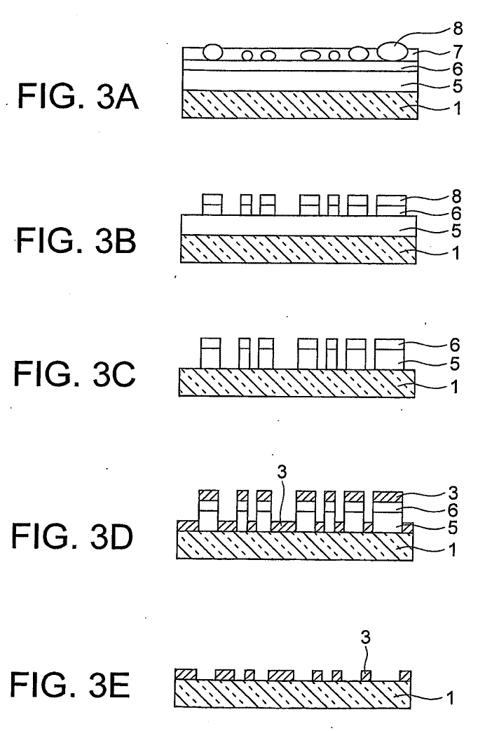

Referring now to FIGS. 3A to 3E, an example of such a manufacturing method is described.

First, the transparent substrate 1 is prepared, and an organic polymer layer 5 of 50 nm to 150 nm in thickness is applied on the transparent substrate 1, if necessary. It is preferable to use the organic polymer layer 5, so as to increase the aspect ratio of the mask patterns when etching is performed on the substrate.

An inorganic layer 6 of 5 nm to 30 nm in thickness is then applied onto or deposited on the organic polymer layer 5. This inorganic layer 6 functions as an etching mask when oxygen plasma etching is performed on the lower organic polymer layer 5. The organic polymer layer 5 can be easily etched by oxygen plasma etching, while the inorganic layer 6 can have high tolerance to oxygen plasma etching if made of an appropriate inorganic material. Accordingly, a mask having rod-like portions with a high aspect ratio can be formed, and the liftoff in a later stage can be easily performed. In such a case, it is preferable that the inorganic layer 6 has high etching tolerance to plasma such as SF₆/H₂ or CF₄/H₂.

Lastly, a block copolymer thin film 7 is rotatively applied onto the inorganic layer 6, so as to obtain the material before etching. After the rotative application of a diblock copolymer, annealing is performed on a hot plate or in an oven over a long period of time, so as to form dot-like microdomains 8 (FIG. 3A).

If one of the polymer compositions can be readily removed from the other one of the polymer compositions by etching after a block copolymer is orientated, the remaining orientated nanoscale dot-like microdomains 8 can be used as the etching mask. It is preferable to use a diblock polymer formed with a combination of an aromatic material and an acrylic material, since there is a large etching contrast between the two blocks. For example, the etching rate in RIE greatly differs between polystyrene and polymethylmethacrylate, and the orientated polystyrene domain can be selectively left and used as an etching mask.

After one of the phases in the block copolymer is selectively removed to form dot-like patterns, etching is performed on the lower layer, with the dot-like patterns serving as a mask. However, typical polymers forming a block copolymer cannot tolerate etching performed on a hard substrate. To overcome such a difficulty and achieve such an aspect ratio as to cause the patterns to have the properties as a mask, a pattern transfer technique that involves the inorganic layer 6 is used in this embodiment. By selecting appropriate gas species, a clear difference in etching rate can be created between the organic material containing a polymer and the inorganic material. Therefore, in this embodiment, etching is performed by RIE using oxygen. The inorganic layer 6 is not etched by the oxygen plasma, so that the etching contract between the inorganic layer 6 and the lower organic polymer layer 5 can be made very large. As a result, the organic polymer layer 5 can be etched quickly. Thus, rod-like patterns having a high aspect ratio can be formed (FIG. 3B).

After dot-like patterns are transferred onto the organic polymer layer 5 (FIG. 3C), metal parts 3 are deposited (FIG. 3D). To deposit the metal, a vapor deposition technique or the like can be used. When the polymer is removed through an ashing process, ultrasonic cleaning, or the like, as shown in FIG. 3E, the structure of the metal electrode layer having optical transparency in accordance with an embodiment of the present invention is completed.

The inorganic layer 6 functions as an etching mask when etching or oxygen plasma etching is performed on the lower organic polymer layer 5, for example. Examples of materials that have such characteristics of the inorganic layer 6 include vapor-deposited silicon, silicon nitride, and silicon oxide.

A rotatively-applied siloxane polymer, polysilane, spin-on glass, and the likes are also effective when oxygen plasma etching is performed.

In accordance with the above described embodiment, a metal electrode layer having optical transparency is formed on a substrate or a generating layer.

In the following specific examples, solar cells of various power generation types will be described in detail.

### EXAMPLES

### Example 1

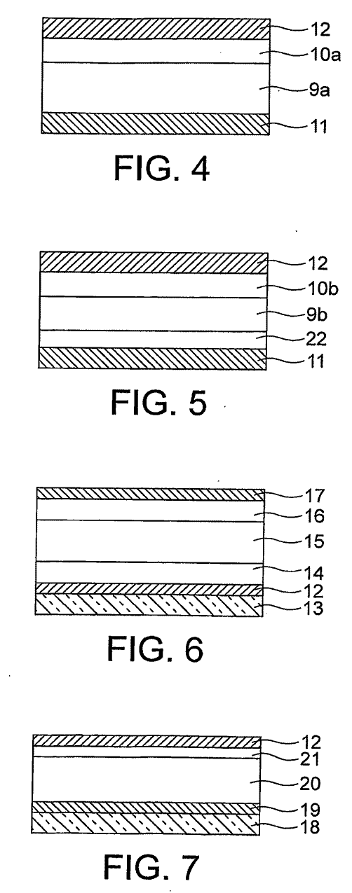

Example 1 concerns a method for manufacturing a single-crystal solar cell. FIG. 4 is a cross-sectional view of a single-crystal Si solar cell that includes an optically-transparent metal electrode layer having openings in accordance with the present invention.

As shown in FIG. 4, a p-type silicon substrate 9a that is p-type single-crystal silicon is first prepared as a semiconductor substrate. The p-type silicon substrate 9a is p-type single-crystal silicon that is formed by slicing a silicon ingot with a multi-wire saw into pieces of 230 μm in thickness. The silicon ingot is doped with boron and is lifted by the Czochralski method. The p-type single-crystal silicon is approximately 2 Ω·cm in specific resistance. The p-type silicon substrate 9a is then thinned to 70 μm through mechanical polishing, and outside diameter processing is performed so that the p-type silicon substrate 9a has a square surface 5-cm on a side.

An n⁺ layer 10a containing a large amount of an n-type impurity element such as phosphorus is formed on one of the principal surfaces of the p-type silicon substrate 9a. The n⁺ layer 10a is formed by a thermal diffusion method. By the thermal diffusion method, the p-type silicon substrate 9a is placed in a high-temperature gas containing phosphorus oxychloride (POCl₃), and an n-type impurity element such as phosphorus is diffused onto one of the principal surfaces of the p-type silicon substrate 9a. In the case where the n⁺ layer 10a is formed by the thermal diffusion method, the n⁺ layer 10a may be formed on both surfaces and at the end portions of the p-type silicon substrate 9a. In this case, however, the unnecessary portions of the n⁺ layer 10a can be removed by immersing the p-type silicon substrate 9a in a fluorine nitrate solution after the subject surface of the n⁺ layer 10a is covered with an acid-resistant resin. In Example 1, thermal diffusion is performed on the p-type silicon substrate 9a in a POCl₃ gas atmosphere at 850° C. for 15 minutes, so as to form the n⁺ layer 10a on the p-type silicon substrate 9a. Here, the sheet resistance value of the n⁺ layer 10a is approximately 50Ω.

After an acid-resistant resin is formed on the n⁺ layer 10a, the p-type silicon substrate 9a is immersed in a fluorine nitrate solution for 15 seconds, so as to remove the portions of the n⁺ layer 10a on which the acid-resistant resin is not formed. The acid-resistant resin is then removed, so that the n⁺ layer 10a remains only on one of the principal surfaces of the p-type silicon substrate 9a. As a result, the thickness of the p-type silicon substrate 9a becomes 50 μm.

A back-face electrode layer 11 is then formed by creating an Al film on a principal surface of the p-type silicon substrate 9a through vacuum vapor deposition. The back-face electrode layer 11 that is an Al film serves as a back-face electrode and a reflection film.

After that, a metal electrode layer 12 is formed on the n⁺ layer 10a, which is to be the light receiving face to receive sunlight.

The inventors discovered a method for achieving a phase separation form of a block copolymer having a dotted structure with 50 nm to 70 nm cycles. The orientated dot-like patterns are transferred onto the sunlight receiving substrate by the later described technique. A metal electrode is deposited onto the transferred structure, and the pattern-transferred portion is removed. The structure is then used as the metal electrode layer 12. This method is described in the following.

A solution formed by diluting a thermosetting resist (THMR IP3250 (a trade name), manufactured by Tokyo Ohka Kogyo Co., Ltd.) with ethyl lactate at 1:3 is rotatively applied onto the light receiving substrate. The structure is then heated under a nitrogen atmosphere in a non-oxidation oven at 250° C. for one hour, so as to cause a thermal curing reaction.

A solution formed by diluting spin-on glass (SOG-5500 (a trade name), manufactured by Tokyo Ohka Kogyo Co., Ltd.) with ethyl lactate is rotatively applied onto the substrate having the resist applied thereon. The structure is then heated under a nitrogen atmosphere in a non-oxidation oven at 250° C. for another hour.

A propylene glycol monomethyl ether acetate solution containing 3 wt % of a polystyrene-polymethylmethacrylate diblock copolymer is mixed with a propylene glycol monomethyl ether acetate solution containing 3 wt % of a polymethylmethacrylate homopolymer, to obtain a block copolymer solution. This solution is rotatively applied onto the substrate. Further, the structure is heated under a nitrogen atmosphere in a non-oxidation oven at 250° C. for 8 hours. The molecular weight of the diblock copolymer is 78000 g/mol at the polystyrene portion, and 170000 g/mol at the polymethylmethacrylate portion. Accordingly, a morphology having dot-like microdomains of polystyrene ranging from 50 nm to 70 nm in size formed in a matrix of polymethylmethacrylate is obtained.

Etching is then performed on the diblock copolymer with 30 sccm of O₂ and a RF power of 100 W at 100 mTorr. Through this process, the matrix of polymethylmethacrylate of the block copolymer is selectively removed, while the polystyrene is not etched. The etching is performed so as to completely etch the polymethylmethacrylate existing between the dots of polystyrene. In this manner, the spin-on glass layer at those portions is completely exposed. With the remaining polystyrene serving as a mask, CF₄-RIE is performed on the spin-on glass layer. Through this etching, the portions of the spin-on glass layer that were the base of the matrix of polymethylmethacrylate are selectively etched, and the dots of polystyrene are transferred onto the spin-on glass layer. With the spin-on glass layer serving as a mask, O₂-RIE is performed on the lower thermosetting resist. As a result, pillar-like patterns with a high aspect ratio is formed at the portions where the polystyrene existed.

An aluminum film of 30 nm in thickness is deposited on the pillar-like patterns by the resistance heating deposition method. After ashing with O₂ plasma is performed, the structure is immersed in water, and is subjected to ultrasonic cleaning. A liftoff process is then carried out to remove the pillar-like patterns. As a result, the metal electrode layer 12 having the desired openings is formed on the sunlight receiving face.

The resultant metal electrode has a mean opening size of approximately 50 nm, and an opening area proportion of approximately 52%. The results of the measurement carried out on the resultant metal transparent electrode at the 500 nm portion show that the transmission rate is approximately 60%, and the resistivity is approximately 30 μΩ·cm.

The properties of the solar cell of Example 1 manufactured in the above manner are evaluated by a solar simulator that emits artificial sunlight of AM 1.5 onto the solar cell of Example 1 at room temperature. The evaluation results show that the conversion efficiency is 13.2%, which is a preferable value. The same evaluation is made on metal materials other than aluminum, to obtain substantially the same results as above.

### Comparative Example 1

An aluminum mesh electrode having a mean opening proportion of 52% is formed at the position of the metal electrode layer in the single-crystal Si solar cell of Example 1 by a photolithography technique. The aluminum mesh electrode is designed so that the opening size is 1 μm, which is 20 times larger than the opening size in Example 1. The same evaluation as above is made on the resultant structure, to find that the conversion efficiency is 11.2%.

### Example 2

Example 2 concerns a method for manufacturing a polycrystalline Si solar cell. FIG. 5 is a cross-sectional view of a polycrystalline Si solar cell that includes an optically-transparent metal electrode layer having openings in accordance with the present invention. The method for manufacturing the polycrystalline Si solar cell is almost the same as the method for manufacturing the single-crystal Si solar cell of Example 1.

As shown in FIG. 5, a p-type silicon substrate 9b that is 250-μm thick polycrystalline silicon cut out of an ingot with a multiwire saw is first formed. Etching and cleaning with NaOH are then performed on the layer that is mechanically damaged on its surface at the time of the ingot cutting. Through the etching and cleaning, a plate-like structure having a 5-cm square surface is formed. The p-type silicon substrate 9b is then placed in a diffusion furnace, and is heated in phosphorus oxychloride (POCl₃) at 850° C. for 30 minutes. In this manner, phosphorus atoms are diffused in the surface of the p-type silicon substrate 9b, and an n⁺ layer 10b that is an n-type semiconductor region of 60Ω/□ in sheet resistance is formed. As a result, a pn junction is formed in the wafer.

An aluminum paste is then applied onto the entire back face, and heating is performed to form a P⁺ layer 22 and a back-face electrode layer 11. The formation of the P⁺ layer 22 is called the BSF (Back Surface Field) method, and is carried out to reduce the impurities that eliminate carriers in the vicinities of electrodes. In the same manner as in Example 1, the metal electrode layer 12 having optical transparency is then formed on the light receiving side that is the opposite side from the back-face electrode layer 11.

The properties of the solar cell of Example 2 manufactured in the above manner are evaluated by a solar simulator that emits artificial sunlight of AM 1.5 onto the solar cell of Example 2 at room temperature. The evaluation results show that the conversion efficiency is 10.3%, which is a preferable value.

### Comparative Example 2

An aluminum mesh electrode having a mean opening proportion of 52% is formed at the position of the metal electrode layer in the solar cell of Example 2 by a photolithography technique. The aluminum mesh electrode is designed so that the opening size is 1 μm, which is 20 times larger than the opening size in Example 1. The same evaluation as above is made on the resultant structure, to find that the conversion efficiency is 9.2%.

### Example 3

Example 3 concerns a method for manufacturing an amorphous Si solar cell. FIG. 6 is a cross-sectional view of the amorphous Si solar cell that includes the metal electrode layer having openings in accordance with the present invention.

The amorphous Si solar cell differs from any of the above described crystalline Si solar cells, in that the light absorption coefficient is large, and the absorption layer can be thinned. However, in a case where a pn junction is formed, carrier traps and recoupling are promptly caused due to structural defects and the likes in the amorphous Si. To counter those problems, an i-layer that is undoped Si on which doping is not performed is formed between a p-type Si layer and an n-type Si layer in the amorphous Si solar cell. The i layer absorbs light, and the carriers divided into holes and electrons reach the n-layer and the p-layer by virtue of the electric field induced in the i-layer. Those carriers then generate electromotive force. Also, as described above, it is preferable that an electrode is formed over the entire surface of the amorphous Si solar cell, so that a contact can be made over the front face of the light emission face.

In the first procedure, a transparent conductive film is formed on a translucent quartz transparent substrate 13. The metal electrode layer 12 is then formed on the transparent conductive film by the method using a block polymer under the same conditions as those in Example 1.

The transparent substrate 13 is placed in a plasma CVD device of a separate formation type, and a gas is selected according to the physical properties required for each layer. The p-layer 14, the i-layer 15, and the n-layer 16 that are amorphous Si films are formed. More specifically, the p-layer 14 that is a p-type Si layer is deposited with the use of a mixed gas of PH₃ and SiH₄. The i-layer 15 that is an i-type Si layer is then deposited on the p-layer 14 with the use of a SH₄ gas. The n-layer 16 that is an n-type silicon layer is then deposited on the i-layer 15 with the use of a mixed gas of B₂H₆ and SH₄. In this manner, a generating layer is formed. The formation of each of those layers is carried out in chambers that are independent of one another so as to prevent impurities from entering each of the layers. The device taken out of the CVD device is then subjected to processing performed by a sputtering device, so as to form a back-face electrode layer 17 made of a silver alloy containing aluminum on the n-layer 16.

Through the above procedures, the amorphous Si solar cell of Example 3 is completed.

The properties of the solar cell of Example 3 manufactured in the above manner are evaluated by a solar simulator that emits artificial sunlight of AM 1.5 onto the solar cell of Example 3 at room temperature. The evaluation results show that the conversion efficiency is 7.5%, which is a preferable value.

### Example 4

Example 4 concerns a method for manufacturing a compound-semiconductor (chalcopyrite) solar cell. FIG. 7 is a cross-sectional view of the compound-semiconductor solar cell that includes the metal electrode layer having openings in accordance with the present invention.

First, a Mo electrode 19 to be a lower electrode is formed on a substrate 18 made of soda lime glass by a vacuum deposition method. Other than molybdenum, it is possible to use titanium, tungsten, or the like as the lower electrode.

A layer called a precursor is then formed by attaching copper (Cu), indium (In), and gallium (Ga) to the structure by a sputtering technique. The precursor is then placed in a furnace, and annealing is performed on the precursor in a hydrogen selenide (H₂Se) gas atmosphere at a temperature ranging from 400° C. to 600° C. In this manner, a CIGS light absorption layer 20 is formed. The annealing process is normally called gas-phase selenizing, or simply, selenizing.

As the procedure for forming the light absorption layer, several techniques have been suggested, such as a technique of performing annealing after the deposition of Cu, In, Ga, and Se. Although gas-phase selenizing is used in Example 4, the procedure for forming the light absorption layer of the present invention is not limited to this example.

A buffer layer 21 that is an n-type semiconductor such as CdS, ZnO, or InS is then stacked on the CIGS light absorption layer 20. The buffer layer 21 is formed by a sputtering technique. The effects of the buffer layer include Cd diffusion into the CIGS layer and inactivation of the grain boundaries.

Laser light is then irradiated so as to reform the CIGS light absorption layer 20 into a contact electrode. The laser light is emitted also onto the buffer layer 21. However, the influence of the existence of the buffer layer 21 is not observed, since the buffer layer 21 is very much thinner than the CIGS light absorption layer 20.

The metal electrode layer 12 to be the upper electrode is then formed over the buffer layer 21 and the CIGS light absorption layer 20 turned into a contact electrode. The formation of the metal electrode layer 12 is carried out by the same technique as that used for forming the block polymer in Example 1.

Through the above procedures, the compound-semiconductor (chalcopyrite) solar cell of Example 4 is completed.

The properties of the resultant solar cell are evaluated by a solar simulator that emits artificial sunlight of AM 1.5 onto the solar cell at room temperature. The evaluation results show that the conversion efficiency is 13.3%, which is a preferable value.

As described so far, each of the embodiments of the present invention provides a solar cell that includes a metal electrode having high light transmission properties while maintaining low resistivity. In such a solar cell, the decrease of the effective incident area that normally causes a decrease of generating efficiency, and the heat loss due to electrode resistance are reduced, and the generating efficiency of the solar cell can be increased accordingly.

It should be understood that the present invention is not limited to the above specific embodiments, and various changes and modifications may be made to those embodiments.

The present invention is not limited to the above embodiments, and the components of the embodiments may be modified and put into practice, without departing from the scope of the invention. The components disclosed in the above embodiments may be appropriately combined to embody various other forms. For example, some of the components may be omitted from the above embodiments, or the components of different embodiments may be combined in an appropriate manner.

1. A solar cell comprising:
a first electrode layer formed on a substrate;
a generating layer formed on the first electrode layer; and
a second electrode layer formed on the generating layer,
at least one of the first electrode layer and the second electrode layer being a metal electrode layer having optical transparency, the metal electrode layer having a plurality of openings that penetrate through the metal electrode layer, the metal electrode layer including metal parts, any two metal parts of the metal electrode layer continuing to each other without a cut portion, the metal electrode layer having a film thickness in the range of 10 nm to 200 nm, and sizes of the openings being equal to or smaller than ½ of the wavelength of light to be used for generating electricity.

2. The cell according to claim 1, wherein the generating layer is formed by stacking a p-type silicon layer as a p-type crystalline silicon layer and an n-type silicon layer as an n-type crystalline silicon layer, the p-type silicon layer and the n-type silicon layer being single-crystal silicon layers.

3. The cell according to claim 1, wherein the generating layer is formed by stacking a p-type silicon layer as a p-type crystalline silicon layer and an n-type silicon layer as an n-type crystalline silicon layer, the p-type silicon layer and the n-type silicon layer being polycrystalline silicon layers.

4. The cell according to claim 1, wherein the generating layer is formed by stacking a p-layer as a p-type semiconductor silicon layer, an i-layer as a undoped silicon layer on which doping is not performed, and an n-layer as an n-type semiconductor silicon layer, the p-layer, the i-layer, and the n-layer being amorphous silicon layers.

5. The cell according to claim 1, wherein the generating layer is a compound semiconductor layer.

6. The cell according to claim 1, wherein the metal electrode layer contains a material selected from the group consisting of Al, Ag, Au, Pt, Ni, Co, Cr, Cu, and Ti.

7. The cell according to claim 1, wherein 95% or more of the area of the metal electrode layer are portions at which a linear distance between continuous metal parts, without any of the openings being interposed in between, is equal to or shorter than ⅓ of the wavelength to be used for generating electricity.

8. The cell according to claim 7, wherein the generating layer is formed by stacking a p-type silicon layer as a p-type crystalline silicon layer and an n-type silicon layer as an n-type crystalline silicon layer, the p-type silicon layer and the n-type silicon layer being single-crystal silicon layers.

9. The cell according to claim 7, wherein the generating layer is formed by stacking a p-type silicon layer as a p-type crystalline silicon layer and an n-type silicon layer as an n-type crystalline silicon layer, the p-type silicon layer and the n-type silicon layer being polycrystalline silicon layers.

10. The cell according to claim 7, wherein the generating layer is formed by stacking a p-layer as a p-type semiconductor silicon layer, an i-layer as a undoped silicon layer on which doping is not performed, and an n-layer as an n-type semiconductor silicon layer, the p-layer, the i-layer, and the n-layer being amorphous silicon layers.

11. The cell according to claim 7, wherein the generating layer is a compound semiconductor layer.

12. The cell according to claim 7, wherein the metal electrode layer contains a material selected from the group consisting of Al, Ag, Au, Pt, Ni, Co, Cr, Cu, and Ti.

13. A method for manufacturing the metal electrode layer of the solar cell according to claim 1,
the method comprising:
generating dot-like microdomains that are phase separation forms of a block copolymer film; and
forming the metal electrode layer having openings by performing etching, with patterns of the microdomains being used as a mask.

14. A method for manufacturing the metal electrode layer of the solar cell according to claim 1,
the method comprising:
preparing a transparent substrate;
forming an organic polymer layer on the transparent substrate;
forming an inorganic layer on the organic polymer layer;
generating dot-like microdomains of a block copolymer film on the inorganic layer;
forming pillar-like portions with an organic polymer and an inorganic material on a surface of the transparent substrate by transferring patterns of the microdomains of the block copolymer film onto the organic polymer layer and the inorganic layer;
forming a metal layer at spaces between the formed pillar-like portions; and
forming the metal electrode layer by removing the organic polymer.
